(19) United States
(12) Patent Application Publication
(10) Pub. No.: US 2006/0141135 A1
(43) Pub. Date: Jun. 29, 2006

(54) Processes for forming layers for electronic devices using heating elements

(76) Inventors: Jian Wang, Goleta, CA (US); Gang Yu, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/025,423

(22) Filed: Dec. 29, 2004

(51) Int. Cl. B05D 5/06; B05D 5/12

(52) U.S. Cl. 427/66; 427/256; 205/104

(57) ABSTRACT

A process for forming an electronic device includes placing a substrate adjacent to a heating element and a deposition source, wherein the deposition source lies between the substrate and the heating element. In one embodiment, the process also includes sending a multiple pulsed signal to the heating element such that the heating element is on and off for a plurality of times. In another embodiment, the process also includes sending a signal to the heating element and depositing a layer over the substrate. Either or both processes further includes depositing a layer over the substrate. Depositing occurs as a result of sending the multiple pulsed signal to the heating element. The layer includes a material from the deposition source.

### BACKGROUND OF THE INVENTION

1. Field of the Invention

The invention relates generally to processes for forming electronic devices, and more specifically, to processes for forming layers for electronic devices using heating elements.

2. Description of the Related Art

Electronic devices, including organic electronic devices, continue to be more extensively used in everyday life. Examples of organic electronic devices include Organic Light-Emitting Diodes (“OLEDs”). A variety of deposition techniques may be used in forming an organic layer used in the OLED. One technique includes heating a solid source to evaporate an organic material in forming the organic layer for the OLED. FIG. 1 includes an illustration of a thermal head 200 that includes a plurality of heating elements 220. A support mechanism 221 and a deposition material sheet 222 overlie the thermal head 200 and heating elements 220. The deposition material sheet 222 includes a small molecule organic material, and in one embodiment is used to form red OLEDs. A display panel substrate 100, including a hole transport layer 120, is placed over the deposition material sheet 222.

At locations where material from the deposition material sheet 222 is to be deposited onto the hole transport layer 120, the corresponding heating elements 220 are energized. When the heating elements are energized, some of the material from the deposition material sheet 222 is evaporated and deposits onto the overlying portion of the hole transport layer 120 to form a red OLED layer 122. The procedure may be repeated for green and blue OLED layers.

During evaporation, the heating elements 220 can receive a direct current (“DC”) signal, which is illustrated as “ON” in FIG. 2. The DC signal stays on until substantially the entire thickness of the red OLED layer is formed, and therefore, is referred to as a “single pulse deposition.” The time of the single pulse deposition depends in part on the thickness; however, the time is typically in a range of 10 seconds to 2 minutes.

While the heating elements are on, the temperature change (“ΔT”) increases as a function of the square root of the time (t^{0.5}) as illustrated in FIG. 3. When the DC signal is terminated at the end of the single pulse deposition, which is illustrated as “OFF” in FIG. 2, the deposition will terminate shortly thereafter. Also, the temperature will decrease as a function of the square root of time, as illustrated in FIG. 3.

The time that passes when the heating elements 220 are ON results in substantial heating that may cause the average temperature of the material being deposited to rise to 250 to 300° C. or even higher during the deposition. Many materials, particularly organic materials, may not be able to be deposited by such a method because the temperature is too high. Such a temperature increase may significantly affect the lifetime of the electronic device that is being formed. This detrimental effect renders the deposition technique as being infeasible.

### SUMMARY OF THE INVENTION

A process for forming an electronic device includes placing a substrate adjacent to a heating element and a deposition source, wherein the deposition source lies between the substrate and the heating element. The process also includes sending a multiple pulsed signal to the heating element such that the heating element is on and off for a plurality of times. The process further includes depositing a layer over the substrate. Depositing occurs as a result of sending the multiple pulsed signal to the heating element. The layer includes a material from the deposition source.

A process for forming an electronic device may alternatively include placing a substrate under a heating element and a deposition source, wherein the deposition source lies between the substrate and the heating element. The process also includes sending a signal to the heating element and depositing a layer over the substrate. Depositing occurs as a result of sending the signal to the heating element. The layer includes a material from the deposition source.

The foregoing general description and the following detailed description are exemplary and explanatory only, and are not restrictive of the invention, as defined in the appended claims.

### BRIEF DESCRIPTION OF THE FIGURES

The invention is illustrated by way of example and not limitation in the accompanying figures.

FIG. 1 includes an illustration of portions of (1) a substrate and a hole transport layer and (2) a thermal head including heating elements and a deposition material sheet.

FIG. 2 includes a plot of a DC signal for use in the thermal head of FIG. 1 using a single pulse deposition.

FIG. 3 includes a plot of temperature change as a function of time during and after the single pulse deposition.

FIGS. 4 and 5 include illustrations of a plan view and a cross-sectional view, respectively, of a micro-heater array.

FIG. 6 includes an illustration of a plan view of a micro-heater array in accordance with an alternative embodiment.

FIG. 7 includes a plot of signals sent to and received by heating elements within the micro-heater array of FIG. 4 during a multiple pulse deposition.

FIG. 8 includes a plot of temperature change as a function of time during the multiple pulse deposition.

FIGS. 9 to 14 include illustrations of cross-sectional views of a portion of a substrate during the formation of an electronic device, wherein at least one of the layers is formed using a multiple pulse deposition.

FIG. 15 includes an illustration of a cross-sectional view of a micro-heater array used in transferring portions of a layer.

FIGS. 16 to 19 include illustrations of cross-sectional views of a portion of a substrate during the formation of an electronic device, wherein at least one of the layers is formed using a multiple pulse deposition using the micro-heater array of FIG. 15.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

A process for forming an electronic device includes placing a substrate adjacent to a heating element and a deposition source, wherein the deposition source lies between the substrate and the heating element. The process also includes sending a multiple pulsed signal to the heating element such that the heating element is on and off for a plurality of times. The process further includes depositing a layer over the substrate. Depositing occurs as a result of sending the multiple pulsed signal to the heating element. The layer includes a material from the deposition source.

In another embodiment, a cumulative time period is a time period that starts when a first on/off cycle starts when depositing the layer at a location over the substrate and ends at the end of the last on/off cycle for depositing the layer at the location. The heating element is off for at least half of the cumulative time period. In a specific embodiment, during the cumulative time period, the heating element is off for at least 90% of the cumulative time period. In another specific embodiment, an averaged temperature increase of the deposition source is no more than 50° C. during the cumulative time period.

In still another embodiment, the heating element is one of a plurality of heating elements arranged in rows, columns, or both. In yet another embodiment, the substrate includes a substrate structure, and placing includes placing the substrate structure and the deposition source in contact with each other.

In a further embodiment, the deposition source includes a small molecule organic material. In another further embodiment, the deposition source includes a polymer.

In one embodiment, a process for forming an electronic device includes placing a substrate under a heating element and a deposition source, wherein the deposition source lies between the substrate and the heating element. The process also includes sending a signal to the heating element and depositing a layer over the substrate. Depositing occurs as a result of sending the signal to the heating element. The layer includes a material from the deposition source.

In another embodiment, depositing includes contacting the substrate and a portion of the deposition source, wherein the portion lies between the substrate and the heating element. Depositing also includes moving the substrate and deposition source away from each other after sending the signal to the heating element, wherein after moving, the portion overlies the substrate and is no longer part of the deposition source. In a specific embodiment, during contacting, the portion adheres to the substrate. In another specific embodiment, the process further includes releasing the portion of the deposition source from the deposition source before contacting the substrate.

In still another embodiment, the signal includes a multiple pulsed signal. In a specific embodiment, a cumulative time period is a time period that starts when a first on/off cycle starts when depositing the layer at a location over the substrate and ends at the end of the last on/off cycle for depositing the layer at the location. The heating element is off for at least half of the cumulative time period. In a more specific embodiment, during the cumulative time period, the heating element is off for at least 90% of the cumulative time period. In another more specific embodiment, an averaged temperature increase of the deposition source is no more than 50° C. during the cumulative time period.

In other embodiments, for any of the foregoing embodiments, the layer includes an organic active layer. Additional embodiments include an electronic device formed by any of the processes of the foregoing embodiments.

Other features and advantages of the invention will be apparent from the following detailed description, and from the claims. The detailed description first addresses Definitions and Clarification of Terms followed by Micro-heater Arrays and Deposition Sources, Fabrication of Electronic Devices, Alternative Embodiments, Advantages, and finally Examples.

1. Definitions and Clarification of Terms

Before addressing details of embodiments described below, some terms are defined or clarified. The term “active” when referring to a layer or material is intended to mean a layer or material that exhibits electronic or electro-radiative properties. An active layer material may emit radiation or exhibit a change in concentration of electron-hole pairs when receiving radiation.

The term “adhere” is intended to mean that a combination of one or more layers, one or more members, or one or more structures are stuck together such that a force is needed to separate such layer(s), member(s) or structure(s) from one another. In one embodiment, adhering may only result in a tacky condition, and in another embodiment, adhering may or may not result in a glued, fused, or other similar permanently connected condition.

The term “adjacent to,” when used to refer to layers in a device, does not necessarily mean that one layer is immediately next to another layer. Layers that directly contact each other are still adjacent to each other.

The terms “array,” “peripheral circuitry” and “remote circuitry” are intended to mean different areas or components of the organic electronic device. For example, an array may include pixels, cells, or other structures within an orderly arrangement (usually designated by columns and rows). The pixels, cells, or other structures within the array may be controlled locally by peripheral circuitry, which may lie within the same organic electronic device as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “averaged,” when referring to a value, is intended to mean an intermediate value between a high value and a low value. For example, an averaged value can be an average, a geometric mean, or a median.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the appropriate potential(s), performs a function. An electronic device may include or be part of a system. An example of an electronic device includes a display, a sensor array, a computer system, an avionics system, an automobile, a cellular phone, or other consumer or industrial electronic product.

The term “heating element” is intended to mean an electrical conductor or resistor, which when current passes through such conductor or resistor, such conductor or resistor serves a principal function of heating a targeted area or region. For the purposes of this specification, a laser is not a heating element.

The term “multiple pulsed deposition” is intended to mean a deposition of a layer or material in which at least two pulsed signals are used during such deposition.

The term “off” is intended to mean a state in which no current or no more than an insignificant amount of current is flowing through a circuit, electronic component, conductor, or any combination thereof.

The term “on” is intended to mean a state in which a significant amount of current is flowing through a circuit, electronic component, conductor, or any combination thereof.

The term “on-pulse” is intended to mean a pulse that corresponds to an on-state.

The term “on/off cycle” is intended to refer to a signal from the beginning of an on-pulse to the beginning of the next on-pulse.

The term “polymer” is intended to mean a material having at least one repeating monomeric unit. The term includes homopolymers having only one kind of monomeric unit, and copolymers having two or more different monomeric units. Copolymers are a subset of polymers. In one embodiment, a polymer has at least 5 repeating units.

The term “precision deposition technique” is intended to mean a deposition technique that is capable of depositing one or more materials over a substrate to a thickness no greater than approximately one millimeter. A stencil mask, frame, well structure, patterned layer or other structure(s) may be present during such deposition.

The term “pulsed signal” is intended to mean a signal having an amplitude that varies as a function of time. An example of a pulsed signal includes a square-wave signal.

The term “radiation-emitting component” is intended to mean an electronic component, which when properly biased, emits radiation at a targeted wavelength or spectrum of wavelengths. The radiation may be within the visible-light spectrum or outside the visible-light spectrum (ultraviolet (“UV”) or infrared (“IR”)). A light-emitting diode is an example of a radiation-emitting component.

The term “radiation-responsive component” is intended to mean an electronic component that can sense or respond to radiation at a targeted wavelength or spectrum of wavelengths. The radiation may be within the visible-light spectrum or outside the visible-light spectrum (UV or IR). Photodetectors, IR sensors, biosensors, and photovoltaic cells are examples of radiation-responsive components.

The term “release”0 is intended to mean to significantly reduce a force holding a layer, material, member, or structure to itself or a different layer, material, member, or structure.

The term “small molecule,” when referring to a compound, is intended to mean a compound which does not have repeating monomeric units. In one embodiment, a small molecule has a molecular weight no greater than approximately 2000 g/mol.

The term “substrate” is intended to mean a workpiece that can be either rigid or flexible and may be include one or more layers of one or more materials, which can include, but are not limited to, glass, polymer, metal or ceramic materials or combinations thereof.

The term “substrate structure” is intended to mean a structure overlying a substrate, wherein the structure serves a principal function of separating or a region within or overlying the substrate from contacting a different object or different region within or overlying the substrate. A substrate structure can include a well structure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an “inclusive or” and not to an “exclusive or.” For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Group numbers corresponding to columns within the Periodic Table of the elements use the “New Notation” convention as seen in the CRC Handbook of Chemistry and Physics, 81^{st} Edition (2000).

Unless otherwise defined, all technical and scientific terms used herein have the same meaning as commonly understood by one of ordinary skill in the art to which this invention belongs. Although suitable methods and materials are described herein for embodiments of the invention, or methods for making or using the same, other methods and materials similar or equivalent to those described can be used without departing from the scope of the invention. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

To the extent not described herein, many details regarding specific materials, processing acts, and circuits are conventional and may be found in textbooks and other sources within the organic light-emitting diode display, photodetector, photovoltaic, and semiconductor arts.

2. Micro-heater Arrays and Deposition Sources

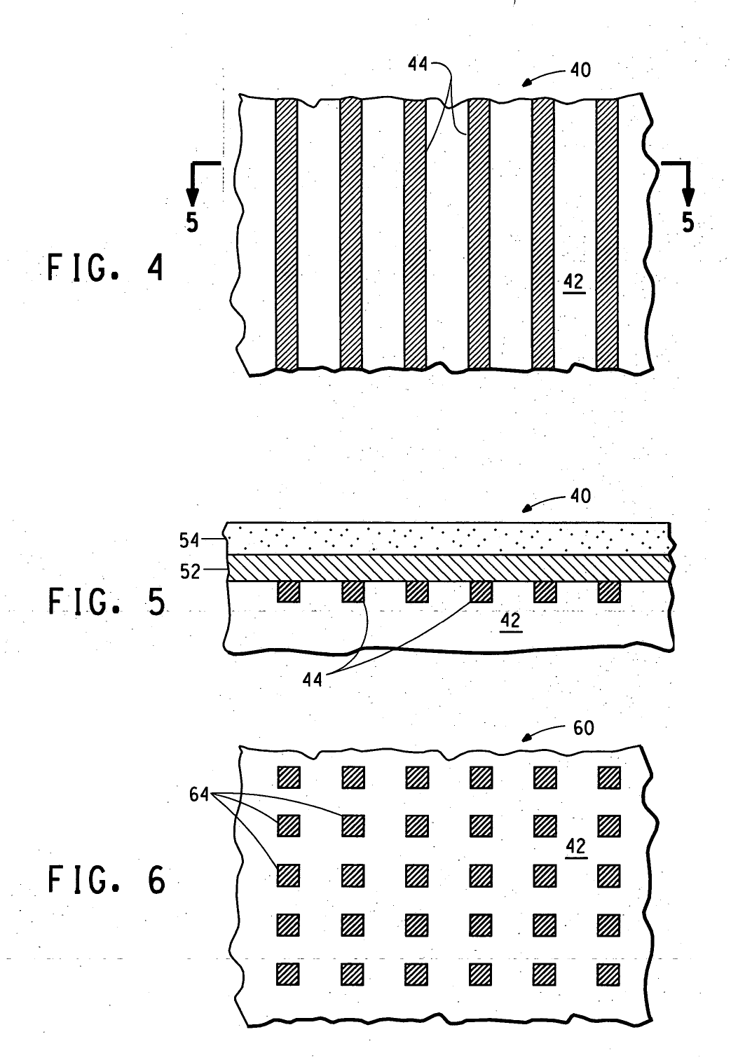

FIGS. 4 and 5 include illustrations of a plan view and a cross-sectional view, respectively, of a portion of a micro-heater array 40. The micro-heater array 40 includes a base material 42, heating elements 44, a protective layer 52, and a deposition source 54. Although not shown, conductive members, a controller, and temperature sensors may be coupled to or lie adjacent to the heating elements 44. For example, the heating elements 44 may be more resistive as compared to conductive members (not shown) connected to the heating elements 44 at a location not shown in FIG. 4. The heating elements 44 are more resistive compared to the conductors, and therefore, generate heat when current flows through the heating circuit(s). Unlike the heating elements 44, the conductors have a significantly lower resistance, and therefore, do not generate a significant amount of heat.

In one embodiment, the base material 42 includes an electrical insulating material, such as glass or a ceramic material. The base material 42 can help to electrically insulate the heating elements 44 from one another. Heating elements 44 within the micro-heater array 40 can include one or more layers including one or more elements from any of Groups 4 to 6, 8 or 10 to 14 of the Periodic Table, or any combination thereof. In addition, conductive metal oxide(s), conductive metal nitride(s) or a combination thereof may be used in place of or in conjunction with any of the elemental metals or alloys thereof. In one embodiment, the heating elements include indium tin oxide (“ITO”), Ni, Cr, W, or any combination thereof. In one embodiment, carbon can be added to a material to increase its resistivity.

The heating elements 44 are illustrated as substantially parallel columns in FIG. 4. The pitch and width of the heating elements 44 may be selected based on a number of different factors. For the purposes of this specification, the pitch is the sum of the widths (as seen from a plan view) of a heating element 44 and a space between two adjacent heating elements. In one embodiment, the pitch of the heating elements 44 within the micro-heater array 40 corresponds to a pitch for pixels within a display or sensors within a sensor array of an electronic device. In another embodiment, the pitch of the heating elements 44 corresponds to the pitch for the electronic components (e.g., sub-pixels) within an electronic device. In still another embodiment, the widths of the heating elements 44 correspond to lengths or widths of electronic components being fabricated. The selection of the material(s) and thickness of the heating elements 44 may be selected to achieve a designed or desired resistance. Materials have been previously described. Resistitivies of the materials may be obtained from reference books or determined empirically. A wide variety of geometric sizes (e.g. lengths and cross-sectional areas) may be used.

In one embodiment, a power density within a range of power densities can be used for the deposition. The range of power densities can be 1 to 100 W/cm², and in a more specific embodiment is 10 to 60 W/cm², and in still a more specific embodiment is 20 to 40 W/cm². In one embodiment, the range of power densities may be used for a targeted temperature, such as 250° C. A linear relationship exists between power and temperature. Therefore, if the targeted temperature is doubled to 500° C., the ranges for the power density can be doubled. The power needed for the heater can be obtained by multiplying the power density times the area of the micro-heater array 40.

The heating elements 44 may be oriented in a different direction compared to what is illustrated in FIG. 4. For example, the heating elements 44 may be oriented in substantially parallel rows, diagonally, or nearly any other orientation. In another embodiment, the heating elements 44 are not substantially parallel to one another. In still another embodiment, the heating elements 44 may be oriented such that they intersect one another. In yet another embodiment, the heating elements may be curved or have sharp bends. In a further embodiment illustrated in FIG. 6, a micro-heater array 60 has discrete heating elements 64. Each of the discrete heating elements 64 may correspond to radiation-emitting or radiation-responsive areas of electronic components to be formed within an electronic device. After reading this specification, skilled artisans will appreciate that nearly any shape or pattern of heating elements may be used. As illustrated in FIG. 5, the heating elements 44 are located within the base material 42. In another embodiment, the heating elements may lie on or over, and not within, the base material 42.

The protective layer 52 can reduce the likelihood of contaminating the deposition source 54 with material(s) that may be present within the heating elements 44 or the base material 42. The protective layer 52 can include an organic or inorganic material. For example the protective layer 52 may include silicon dioxide, silicon nitride, alumina, a relatively high molecular weight polymer, such as a parylene, a fluorinated polymer, a polyimide, or any combination thereof.

In one embodiment, the protective layer 52 is an electrically insulating material to reduce the likelihood of an electrical connection or leakage path between the heating elements 44 or any other conductive members (not shown) or electronic components (not shown) coupled to the heating elements 44. After reading this specification, skilled artisans will appreciate that many other material(s) or one or more additional layers may be part of the protective layer 52.

The deposition source 54 can include one or more layers of one or more materials. The deposition source 54 can have nearly any thickness. In one embodiment, the deposition source 54 has an initial thickness of at least 0.1 micron, and in another embodiment, the deposition source 54 has an initial thickness of at least 1 micron. Although no upper limit is known for the deposition source 54, a practical limit may be approximately 100 microns.

The deposition source 54 can be used to deposit a variety of different materials. The following paragraphs include only some but not all of the materials that may be used within the deposition source 54. In one embodiment, one or more materials for an organic layer within an electronic device are formed using the micro-heater array 40 with the deposition source 54. The organic layer can include an organic active layer, (e.g., a radiation-emitting organic active layer or a radiation-responsive organic active layer), a filter layer, charge injection layer, charge transport layer, charge blocking layer, or any combination thereof. The organic layer may be used as part of a resistor, transistor, capacitor, diode, etc.

For a radiation-emitting organic active layer, suitable radiation-emitting materials include one or more small molecule materials, one or more polymeric materials, or a combination thereof. Small molecule materials may include those described in, for example, U.S. Pat. No. 4,356,429 (“Tang”); U.S. Pat. No. 4,539,507 (“Van Slyke”); U.S. Patent Application Publication No. US 2002/0121638 (“Grushin”); and U.S. Pat. No. 6,459,199 (“Kido”). Alternatively, polymeric materials may include those described in U.S. Pat. No. 5,247,190 (“Friend”); U.S. Pat. No. 5,408,109 (“Heeger”); and U.S. Pat. No. 5,317,169 (“Nakano”). Exemplary materials are semiconducting conjugated polymers. Examples of such polymers include poly(paraphenylenevinylene) (PPV), PPV copolymers, polyfluorenes, polyphenylenes, polyacetylenes, polyalkylthiophenes, poly(n-vinylcarbazole) (PVK), and the like. In one specific embodiment, a radiation-emitting active layer without any guest materials may emit blue light.

For a radiation-responsive organic active layer, suitable radiation-responsive materials may include many conjugated polymers and electroluminescent materials. Such materials include for example, many conjugated polymers and electro- and photo-luminescent materials. Specific examples include poly(2-methoxy,5-(2-ethyl-hexyloxy)-1,4-phenylene vinylene) (“MEH-PPV”) and MEH-PPV composites with CN-PPV.

The location of a filter layer may be between an organic active layer and a user side of the electronic device. A filter layer may be part of a substrate, an electrode (e.g., an anode or a cathode), a charge transport layer, a charge injection layer, a charge blocking layer; lie between any one or more of the substrate, electrodes, charge transport layer, charge injection layer, charge blocking layer; or any combination thereof. In another embodiment, the filter layer may be a layer that is fabricated separately (while not attached to the substrate) and later attached to the substrate at any time before, during, or after fabricating the electronic components within the electronic device. In this embodiment, the filter layer may lie between the substrate and a user of the electronic device.

When the filter layer is separate from or part of the substrate, or when the filter lies between the substrate and an electrode closest to the substrate, suitable materials include many different organic materials including polyolefins (e.g., polyethylene or polypropylene); polyesters (e.g., polyethylene terephthalate or polyethylene naphthalate); polyimides; polyamides; polyacrylonitriles and polymethacrylonitriles; perfluorinated and partially fluorinated polymers (e.g., polytetrafluoroethylene or copolymers of tetrafluoroethylene and polystyrenes); polycarbonates; polyvinyl chlorides; polyurethanes; polyacrylic resins, including homopolymers and copolymers of esters of acrylic or methacrylic acids; epoxy resins; Novolac resins; and combinations thereof.

For a hole-injection layer, hole transport layer, electron-blocking layer, or any combination thereof, suitable materials include polyaniline (“PANI”), poly(3,4-ethylenedioxythiophene) (“PEDOT”), organic charge transfer compounds, such as tetrathiafulvalene tetracyanoquinodimethane (TTF-TCQN), hole transport materials as described in Kido, and combinations thereof.

For an electron-injection layer, electron-transport layer, hole-blocking layer, or any combination thereof, suitable materials include metal-chelated oxinoid compounds (e.g., Alq₃); phenanthroline-based compounds (e.g., 2,9-dimethyl-4,7-diphenyl-1,10-phenanthroline (“DDPA”), 4,7-diphenyl-1,10-phenanthroline (“DPA”)); azole compounds (e.g., 2-(4-biphenyl)-5-(4-t-butylphenyl)-1,3,4-oxadiazole (“PBD”), 3-(4-biphenyl)-4-phenyl-5-(4-t-butylphenyl)-1,2,4-triazole (“TAZ”); electron-transport materials as described in Kido, a diphenylanthracene derivative, a dinaphthylanthracene derivative, 4,4-bis(2,2-diphenyl-ethen-1-yl)-biphenyl (“DPVBI”), 9,10-di-beta-naphthylanthracene, 9,10-di-(naphenthyl)anthracene, 9,10-di-(2-naphthyl)anthracene (“ADN”), 4,4′-bis(carbazol-9-yl)biphenyl (“CBP”), 9,10-bis-[4-(2,2-diphenylvinyl)-phenyl]-anthracene (“BDPVPA”), anthracene, N-arylbenzimidazoles (such as “TPBI”), 1,4-bis[2-(9-ethyl-3-carbazoyl)vinylenyl]benzene, 4,4′-bis[2-(9-ethyl-3-carbazoyl)vinylenyl]-1,1′-biphenyl, 9,10-bis[2,2-(9,9-fluorenylene)vinylenyl]anthracene, 1,4-bis[2,2-(9,9-fluorenylene)vinylenyl]benzene, 4,4′-bis[2,2-(9,9-fluorenylene)vinylenyl]-1,1′-biphenyl, perylene, substituted perylenes, tetra-tert-butylperylene (“TBPe”), bis(3,5-difluoro-2-(2-pyridyl)phenyl-(2-carboxypyridyl) iridium III (“F(lr)Pic”), a pyrene, a substituted pyrene, a styrylamine, a fluorinated phenylene, oxidazole, 1,8-naphthalimide, a polyquinoline, one or more carbon nanotubes within PPV; and combinations thereof.

For an electronic component, such as a resistor, transistor, capacitor, etc., the organic layer may include one or more of thiophenes (e.g., polythiophene, poly(alkylthiophene), alkylthiophene, bis(dithienthiophene), alkylanthradithiophene, etc.), polyacetylene, pentacene, phthalocyanine, and combinations thereof.

Examples of organic dyes include 4-dicyanmethylene-2-methyl-6-(p-dimethyaminostyryl)4H-pyran (DCM), coumarin, pyrene, perylene, rubrene, derivatives thereof, and combinations thereof.

Examples of organometallic materials include functionalized polymers comprising functional groups coordinated to at least one metal. Exemplary functional groups contemplated for use include carboxylic acids, carboxylic acid salts, sulfonic acid groups, sulfonic acid salts, groups having an OH moiety, amines, imines, diimines, N-oxides, phosphines, phosphine oxides, β-dicarbonyl groups, and combinations thereof. Exemplary metals contemplated for use include lanthanide metals (e.g., Eu, Tb), Group 7 metals (e.g., Re), Group 8 metals (e.g., Ru, Os), Group 9 metals (e.g., Rh, Ir), Group 10 metals (e.g., Pd, Pt), Group 11 metals (e.g., Au), Group 12 metals (e.g., Zn), Group 13 metals (e.g., Al), and combinations thereof. Such organometallic materials include metal chelated oxinoid compounds, such as tris(8-hydroxyquinolato)aluminum (Alq₃); cyclometalated iridium and platinum electroluminescent compounds, such as complexes of iridium with phenylpyridine, phenylquinoline, or phenylpyrimidine ligands as disclosed in published PCT Application WO 02/02714, and organometallic complexes described in, for example, published applications US 2001/0019782, EP 1191612, WO 02/15645, WO 02/31896, and EP 1191614; and mixtures thereof.

Examples of conjugated polymers include poly(phenylenevinylenes), polyfluorenes, poly(spirobifluorenes), copolymers thereof, and mixtures thereof.

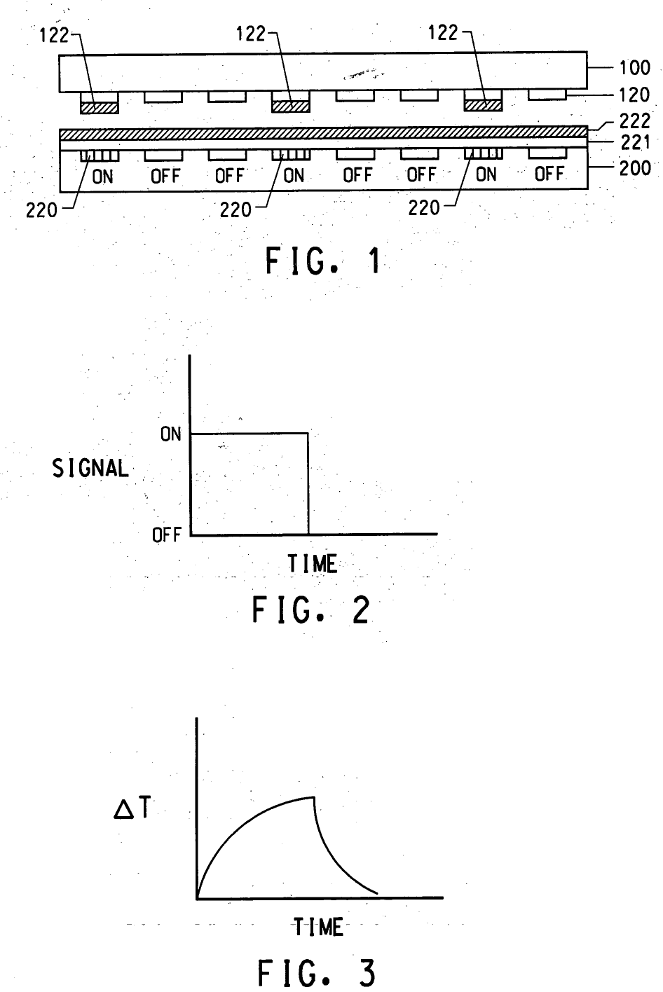

The operation of the micro-heater array 40 with the deposition source 54 is performed using multiple pulses through one or more of the heating elements 44 to deposit material from the deposition source 54 over or under a different substrate. Referring to FIG. 7, the multiple pulses may switch between an on-state and an off-state during a cumulative time period. In one embodiment, the cumulative time period is a time period that starts when a first on/off cycle starts when depositing a layer and ends at the end of the last on/off cycle for depositing the same layer. Within the cumulative time period, the time periods that each of the heating elements 44 are on and off may be the same or may be different from on another. In still another embodiment, the time period for each on-pulse may be the same or different compared to other on-pulses, and the time for each off-pulse may be the same or different compared to other off-pulses. In one non-limiting embodiment, the time any or all of the heating elements 44 are off during a deposition time period is at least 90% of the cumulative time period. In one embodiment, the time period for the on-pulse in FIG. 2 is substantially equal to sum of the time periods for the on-pulses as illustrated in FIG. 7. A difference between the single pulse and multiple pulses is that the heating elements 44 are off for a significant time during the cumulative time period when the multiple pulse embodiment is used.

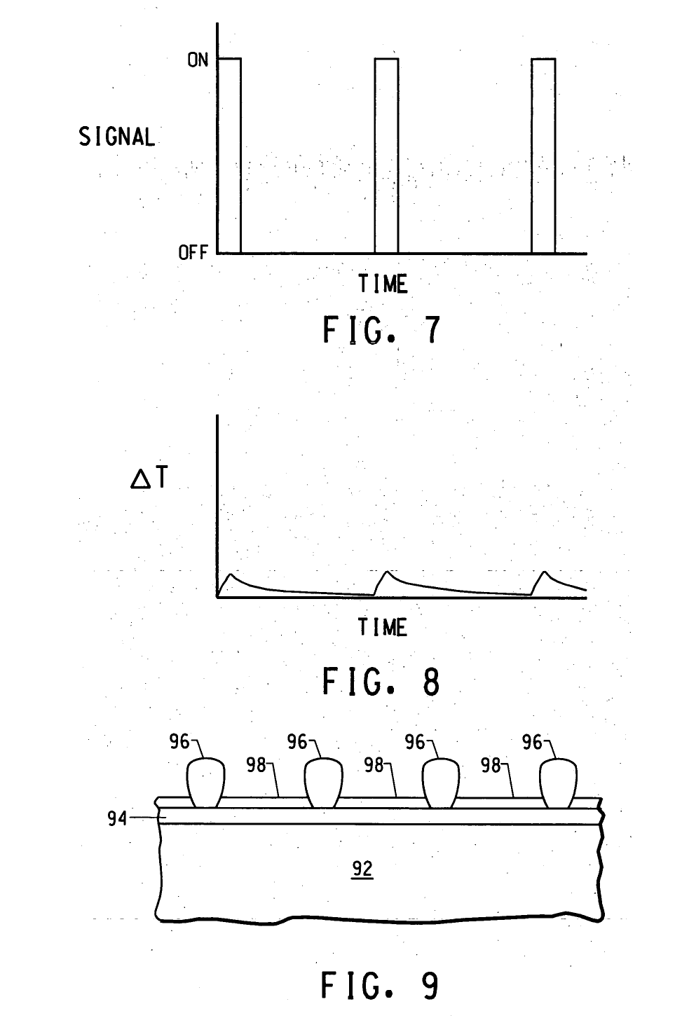

Referring to FIG. 8, the temperature change in response to the pulse time is substantially the same function as illustrated in FIG. 3. Therefore, for any one of the heating elements 44, the temperature will increase asymptotically during the on-pulse and will exponentially decay while the heating elements 44 are off. Unlike FIG. 3, the temperature rise will be much less because the on-pulses are each relatively short compared to the single pulse deposition technique.

The temperature of the deposition source 54 will vary as a function of the distance from the heating elements 44. The temperature of the deposition source 54 along its surface closest to the heating elements 44 can approach the melting or sublimation point of the material within the deposition source 54. The temperature of the deposition source 54 at points away from the heating elements 44 does not rise nearly as much because the pulsed heating help to keep the heating more localized near the heating elements 44. The temperature measurements along the thickness of the deposition source 54 decrease exponentially as a function of the distance from the heating elements 44. For the purposes of this specification, an averaged temperature of the deposition source 54 is an averaged value of temperature measurements taken along a thickness of the film (i.e., in a direction substantially perpendicular to the surface of the micro-heater array 40). The increase in the averaged temperature of the deposition source 54 during a deposition is significantly less because the time period of the on-pulse is relatively short.

Therefore, the entire deposition cycle may take place with an averaged temperature change significantly less than 50° C. In one specific embodiment, the increase in the averaged temperature during a deposition cycle is no greater than approximately 10° C. If the ambient temperature is 20° C., the averaged temperature of the deposition source 54 may be no greater than 70° C. in one embodiment, and no greater than 30° C. in another embodiment.

If a single on-pulse would be used, the heating of the deposition source 54 would not be as localized as it would be for the pulsed heating. While not outside of the scope of some embodiments of the present invention, the single on-pulse deposition process would have a significantly greater increase in the average temperature of the deposition source 54 because more heat would be transferred to the deposition source 54. If the temperature increase is too high, the material of the deposition source 54 may be adversely affected.

The circuits and electronic components for generating and sending the pulse signals to the heating elements are conventional within the semiconductor and electrical arts. In addition to a square-wave pattern as illustrated in FIG. 7, other waveforms can be used, such as continuous curves, including those having a semicircular shape, hyperbolic shape, or other similar shape. In one embodiment, the time period for each of the on-pulses is in a range of approximately 0.1 to 100 ms, and the time period for one pulse cycle (one on/off cycle) is in a range of approximately 0.01 to 10 seconds. A ratio of the time period for each of the on-pulses to the sum of the time period for each of the pulse cycles is no greater than 1:2 in one embodiment, 1:5 in another embodiment, and 1:10 in still another embodiment. Note that many other time periods for on-pulses and on/off cycles may be used and not depart from the scope of the present invention. Further, each of the time periods for any one of the on-pulses may be the same or different from the other on-pulses, and each of the time periods for any one of the on/off cycles may be the same or different from the other on/off cycles.

After reading this specification, skilled artisans will appreciate that the number of on-pulses can vary depending on a number of factors including: characteristics of the heating elements 44, the signal used for the on-pulses (e.g., current, voltage, waveform, time per on-pulse, etc.), the material(s) being deposited from the deposition source 54, the thickness of the deposition source 54 at the time of deposition, whether the protective layer 52 is present, and if present, its characteristics (e.g., thermal conductance or thermal resistance).

While many factors can affect the deposition rate, empirical data may be generated for a variety of conditions to better approximate the deposition rate. In one embodiment, a test substrate is used to determine the deposition rate for the micro-heater array 40. Based on the data collected for the test substrate, the deposition time and number of pulses used may be calculated based on the data collected.

In one embodiment, before using the micro-heater array 40 with the deposition source 54 in a production mode, a user calibrates the deposition rate for an on-pulse or for a set of on-pulses. In one embodiment, a single on-pulse is used, and the thickness of the layer deposited onto another substrate is measured to give the deposition rate. In another embodiment, several on-pulses are used to deposit a layer on that other substrate. A conventional counter may be used to count the on-pulses sent to any one or more heating elements 44. The thickness of the layer is measured, and the deposition per on-pulse is calculated by dividing the thickness of the deposited layer by the number of on-pulses used to deposit the corresponding thickness. In one embodiment, an organic active layer is to be formed to a thickness of approximately 80 nm. If the deposition rate during an on-pulse is approximately 0.1 nm, the total number of on-pulses used to achieve approximately 80 nm will be 800 on-pulses.

3. Fabrication of Electronic Devices

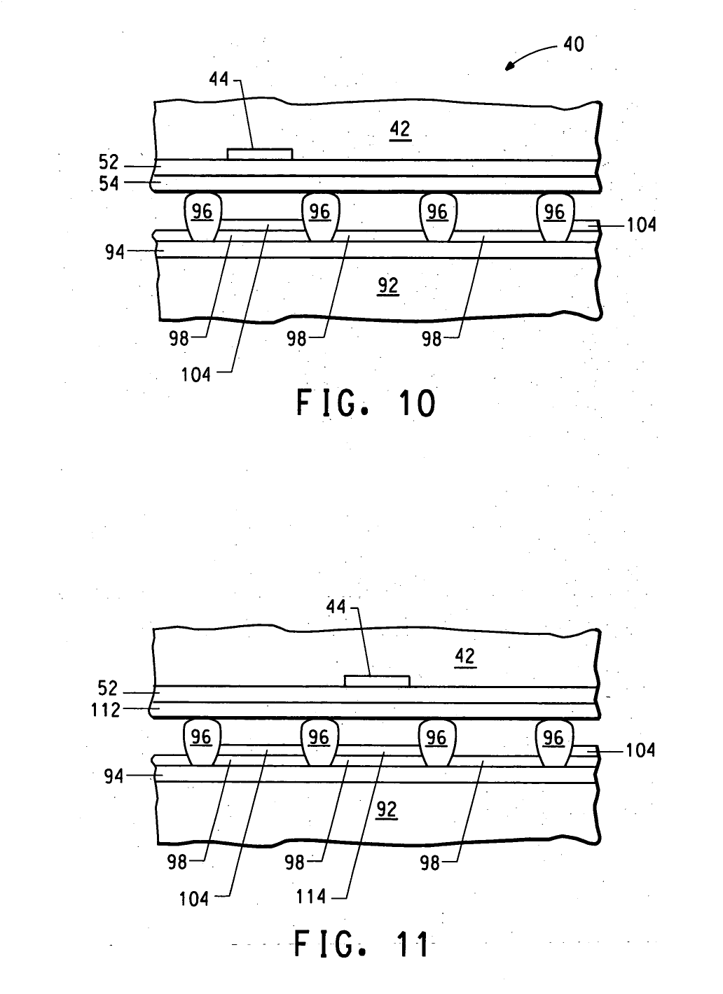

The micro-heater array 40 and deposition source 54, as previously described, may be used in forming electronic devices as will be described in FIGS. 9 to 19. The electronic devices and their fabrication processes are meant to illustrate and not limit the scope of the present invention.

FIG. 9 includes an illustration of a substrate 92 that may be used in forming a passive matrix display for an electronic device. The substrate 92 can be rigid or flexible and may contain an organic or inorganic material as is conventionally used within the organic electronic arts. A first electrode 94 overlies the substrate 92. In one embodiment, the first electrode 94 is an anode. Although not shown, the first electrode 94 is one of a set of first electrodes that are oriented in substantially parallel strips that have lengths extending from side to side as illustrated in FIG. 9.

Substrate structures 96 are formed over the substrate 92 and first electrodes 98. In one the embodiment, the substrate structures 96 are cathode separators, as conventionally used within passive matrix displays within the organic electronic arts. In another embodiment, the substrate structures can be well structures and have a similar or different shape compared to the substrate structures 92 as illustrated in FIG. 9. Such well structures may be used in a passive matrix or active matrix display. In one embodiment, each of the substrate structures 96 has a width in a range of approximately 2 to 10 microns and a height in a range of approximately 2 to 5 microns. In this particular embodiment, the substrate structures 96 are narrower near the substrate 92 as opposed to a point further from the substrate 92. In another embodiment (not shown), the substrate structures 96 are widest near the substrate 92 and are tapered as the distance from the substrate 92 increases, and in still another embodiment, the substrate structures 92 have substantially the same width along its thickness. The materials used for the substrate structures 96 can be an inorganic material (e.g., silicon dioxide, silicon nitride, etc.) or an organic material (e.g., photoresist, polyimide, or other similar material) and are formed using conventional deposition and lithographic techniques. In one embodiment, the substrate structures 96 may include a black material in order to improve the contrast ratio due to ambient light reaching the display from a user side of the electronic device.

An optional charge injection, charge transport, or charge blocking layer, or any combination thereof can be formed over the first electrodes 94. In one embodiment, a hole transport layer 98, which is a type of charge blocking layer, may be formed over the first electrode 94 and between the substrate structures 96. The material used for the hole transport layer 98 can include polyaniline, PEDOT, or other material conventionally used for a hole transport layer within the organic electronic arts. The thickness of the charge injection, charge transport, or charge blocking layer, or any combination thereof can be in a range of approximately 30 to 500 nm, and in one embodiment, the thickness is in a range of approximately 100 to 250 nm.

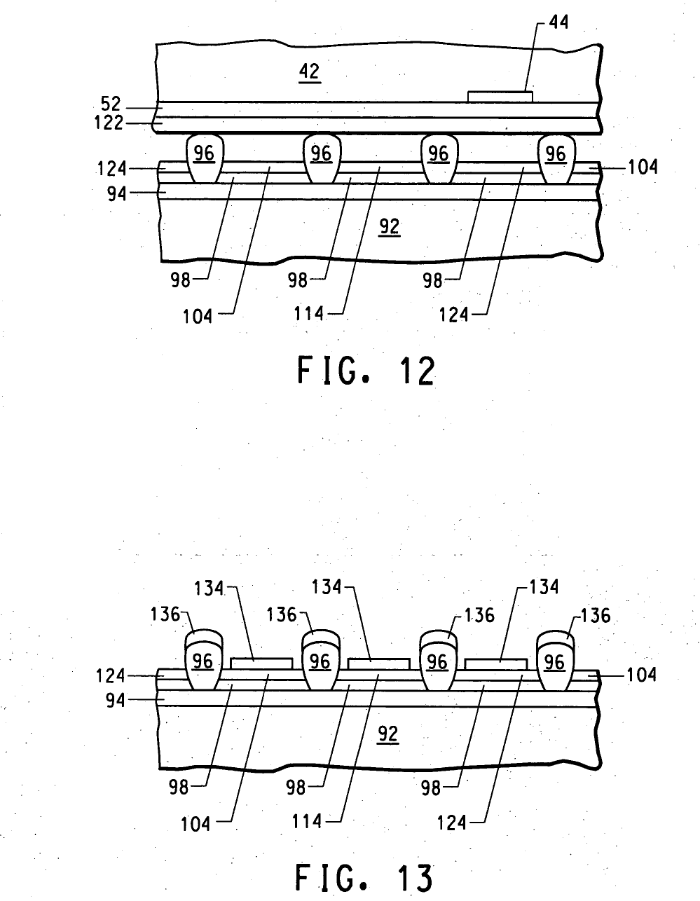

The micro-heater array 40, including the heating elements 44 and deposition source 54, is placed over the substrate 92 as illustrated in FIG. 10. In this specific embodiment, the deposition source 54 contacts or is in close proximity to substrate structures 96. The use of the substrate structures 96 can help limit the deposition to a region between a pair of substrate structures 96. More specifically, referring to FIG. 10, heating element 44 receives multiple on-pulses during a deposition cycle to heat the deposition source 54, which in turn allows a first organic active layer 104 to become deposited over a portion of the hole transport layer 98. In another embodiment, other heating elements are present over the other portions of the hole transport layer 98 but are not shown in FIG. 10. In this alternative embodiment, those heating elements would not be activated (e.g., pulsed) during the formation of the first organic layer 104.

Although not shown, other regions between some at least some of the other substrate structures 96 may also receive the first organic active layer 104. In one the embodiment, one or all of the heating elements 44, which are used to heat the deposition source 54, when forming the first organic layer 104, receive on-pulses at one time. In another embodiment, such heating elements 44 are operated similar to scan lines, in that on-pulses would be sent at different times to different heating elements 44, similar to activating scan lines within a display during the time in which the display is being used to present an image to a user.

The material for the deposition source 54 and first organic layer 104 in this particular embodiment are conventional for organic active layers used in the organic electronic arts. The thickness typically is in a range of approximately 50 to 100 nm. The deposition can occur by evaporation, condensation, liquid deposition, or other similar mechanism.

FIG. 11 illustrates a similar deposition, however a deposition source 112 is used to form a second organic active layer 114. In this embodiment, the deposition parameters may be the same or different from those parameters used in forming the first organic active layer 104. The thickness of the second organic active layer is typically in a range of approximately 50 to 100 nm.

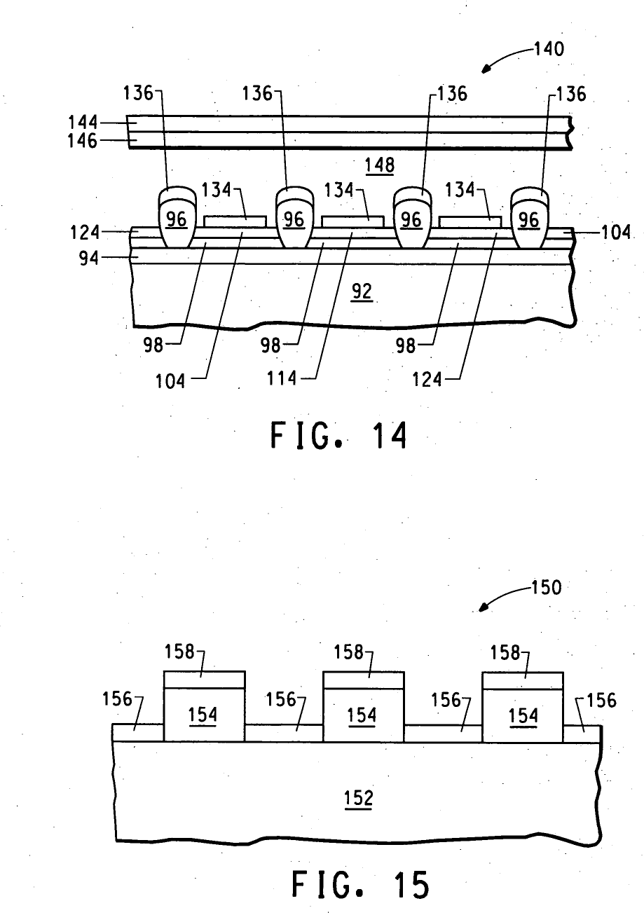

FIG. 12 illustrates a similar deposition, however a deposition source 122 is used to form a third organic active layer 124. In this embodiment, the deposition parameters may be the same or different from those parameters used in forming the first organic active layer 104 or the second organic active layer 114. The thickness of the third organic active layer 124 is typically in a range of approximately 50 to 100 nm.

In one embodiment the first organic active layer 104 is a red radiation-emitting layer, the second organic active layer 114 is a green radiation-emitting layer, and the third organic active layer 124 is a blue radiation-emitting layer. If a monochromatic display is being formed, the first, second, and third organic active layers 104, 114, and 124 would have substantially the same composition. Further, in a monochromatic display, the same deposition source with heating elements 44 may be present over the other portions of the hole transport layer 98.

Second electrodes 134 and conductive members 136 may be deposited over substantially all of the array as illustrated in FIG. 13. In one embodiment, the second electrodes 134 are cathodes for the electronic components, and have lengths that are substantially parallel to one another and substantially perpendicular to the first electrodes 94. The conductive members 136 may be allowed to electrically float or may be connected to a fixed potential, such as Vₛₛ or V_{dd}. The conductive members 136 are not used for an electrical function within the array.

Other circuitry not illustrated in FIGS. 9 to 13 may be formed using any number of the previously described or additional layers. Although not shown, additional insulating layer(s) and interconnect level(s) may be formed to allow for circuitry in peripheral areas (not shown) that may lie outside the array. Such circuitry may include row or column decoders, strobes (e.g., row array strobe, column array strobe), or sense amplifiers.

A lid 144 with an optional desiccant 146 may be attached to the substrate 92 at locations outside the array to form a substantially completed electronic device 140. A gap 148 lies between the lid 144 and the second electrodes 134. In one embodiment, radiation is emitted from or received by the organic active layers 104, 114, and 124 via the user side of the substrate 92. In this-embodiment, the materials used for the lid 144 and desiccant 146 and the attaching process are conventional.

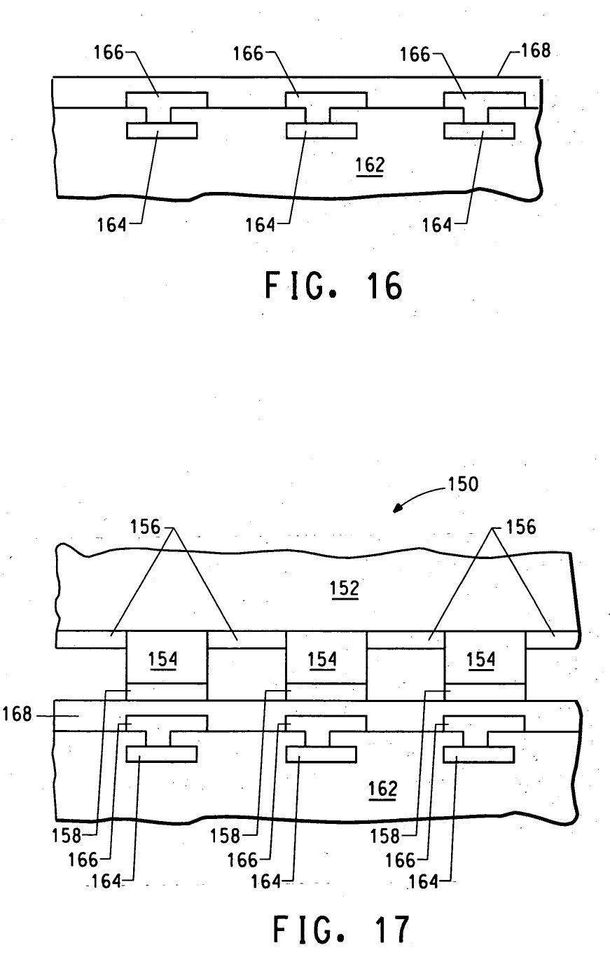

In another embodiment, a micro-heater array 150, as illustrated in FIG. 15 may be used for transferring portions 158 of a layer to a different substrate. Any one or more of the materials used for the base material 42 in FIG. 4 may be used for the base material 152. The heating elements 154 may include any one or more of the material(s) as described with respect to heating elements 44 in FIG. 4. In one embodiment, the surfaces of the heating elements 154 allow the portions 158, which are a deposition source in this embodiment, to be released upon the proper application of a signal or signals to the heating elements 154.

In one embodiment, the micro-heater array 150 can be prepared as described below. The heating elements 154 may be fluorinated or include a fluorine-containing compound along an exposed surface in one embodiment. A deposition source material may be formed over substantially all or a portion of the micro-heater array 150. In one embodiment illustrated in FIG. 15, portions 156 and 158 have substantially the same composition; however, portions 158 are to be transferred to another substrate and portions 156 should remain attached to the base material 152. Although not shown, cooling elements may reside within the base material 152 to keep the portions 156 significantly cooler than the portions 158. The materials used for portions 156 and portions 158 may be any one or more of the materials previously described with respect to the deposition source 54.

FIG. 16 includes an illustration of a cross-sectional view of a portion of a substrate 162. The portion of the substrate 162 in FIG. 16 may include a portion of an active matrix display. Pixel driving circuits, illustrated as blocks 164 in FIG. 16, may reside within the substrate 162. Openings within the substrate 162 may be formed to allow first electrodes 166 to be subsequently formed over contact portions of the pixel driver circuits 164. The first electrodes 166 may be anodes or cathodes for electronic components being formed. At this point in the process, an optional charge injection, charge transport, charge blocking layer, or any combination thereof can be formed over the first electrodes 166. In one embodiment, a hole transport layer 168 is formed over the first electrodes 166.

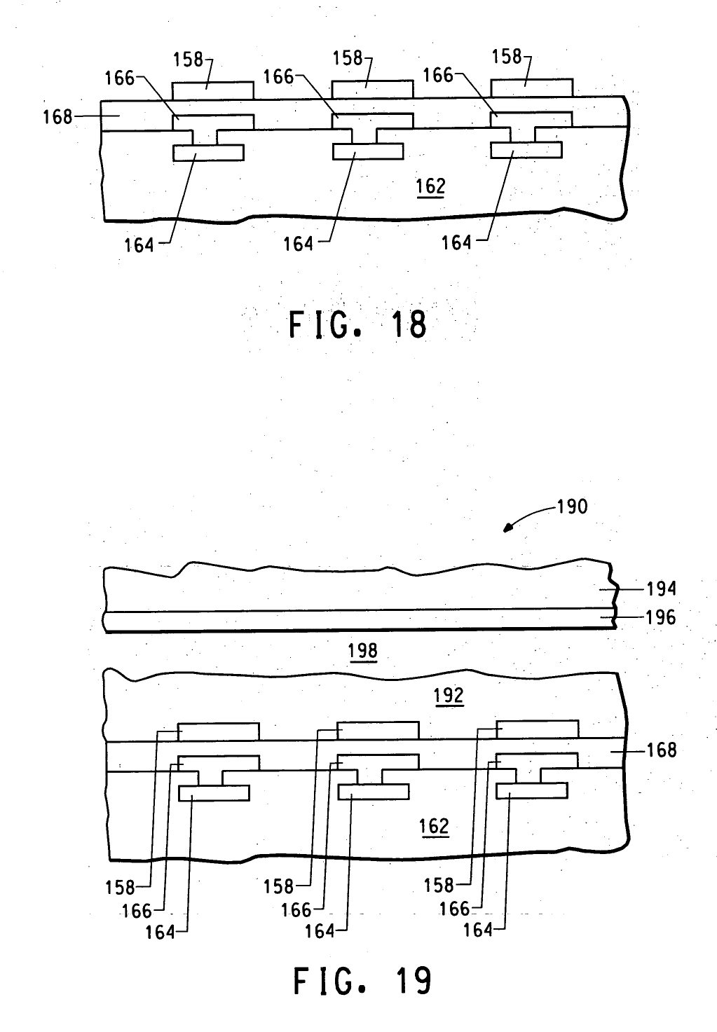

The micro-heater array 150 is then placed adjacent to the substrate 162 as illustrated in FIG. 17. In one embodiment, the portions 158 include an organic active layer to be used within electronic components. The portions 158 come in contact with or lie adjacent to the hole transport layer 168 at locations above the first electrodes 166. One or more on-pulses are sent through the heating elements 154 which allow layer 158 to be released from the heating elements 154 and adhere to the hole transport layer 168. In one embodiment, the transfer operation may be facilitated by using gravity to aid in transferring the portions 158 from the micro-heater array 150 to locations over the substrate 162.

The micro-heater array 150 is moved away from the substrate 162 thereby forming the structures as illustrated in FIG. 18. In one embodiment, the portions 158 may be the same or different compared to one another. In one embodiment, the portions 158 may have substantially the same composition and one or more guest materials, one or more dyes, or any combination thereof are added to any one or more of the portions 158. The actual materials and thickness used for portions 158 are conventional for organic active layers used in the organic electronic arts. In another embodiment, the portions 158 are substantially identical to one another in forming a monochromatic display.

Other circuitry not illustrated in FIGS. 16 to 18 may be formed using any number of the previously described or additional layers. Although not shown, additional insulating layer(s) and interconnect level(s) may be formed to allow for circuitry in peripheral areas (not shown) that may lie outside the array. Such circuitry may include row or column decoders, strobes (e.g., row array strobe, column array strobe), or sense amplifiers.

A lid 194 with an optional desiccant 196 can be attached to the substrate 162 at locations outside the array to form a substantially completed electronic device 190. A gap 198 lies between the lid 194 and the second electrode 192. In one embodiment, radiation is emitted from or received by the portions 158 via the user side of the substrate 162. In this embodiment, the materials used for the lid 194 and desiccant 196 and the attaching process are conventional.

4. Alternative Embodiments

A number of additional alternative embodiments are described below. The alternative embodiments described herein are meant to illustrate and not limit the scope of the present invention, as many other embodiments are possible.

The electronic devices 140 and 190 may have one or more of a charge injection, charge transport, or charge blocking layer formed by a deposition technique using a micro-heater array similar to micro-heater array 40 or 150. Such one or more charge injection, charge transport, or charge blocking layer may be used instead of or in conjunction with the hole transport layer 98 or 168. In one embodiment, the optional charge injection, charge transport, or charge blocking layer may be formed over the organic active layers 104, 114, or 124 and the second electrodes 134. In one embodiment, any one or more of the organic active layers 104, 114, or 124, or portions 158 may be replaced by one or more organic active layers deposited using a conventional method, such as spin coating, ink-jet printing, solution dispensing, or the like, and another layer can be formed using the micro-heater array 40 or 150.

When the micro-heater array is used to vapor deposit a layer, the micro-heater array may be positioned so that the substrate overlies the micro-heater array or side-by-side with the micro-heater array. When the micro-heater array is used to deposit a layer as a liquid or a solid, the micro-heater array may be positioned so that the substrate underlies the micro-heater array to take advantage of gravity.

A wide variety of electronic devices can be made using the processes described here. In one embodiment, the electronic device includes a display, where the display includes electronic components that are radiation-emitting components. Embodiments described herein can be used for bottom emission (emission through the substrate). In another embodiment, a top emission (emission through the encapsulating layer, lid, or both) display is formed. A transparent encapsulation layer, transparent lid, or a combination thereof may be used in order for a significant portion of the radiation (e.g., at least 70% of the radiation) to be transmitted through such encapsulation layer, lid, or combination thereof. If a desiccant is used, it should allow sufficient transmission of radiation or should be placed at locations where it would not substantially interfere with radiation being emitted from or received by the electronic device.

In another embodiment, the electronic device includes an array of radiation sensors or photovoltaic cells. In such an embodiment, the electronic components are radiation-responsive components.

Many other embodiments are possible but are not described. For example, after reading this specification, skilled artisans will know how to combine any one or more of the features for any of the described embodiments with each other to form new embodiments.

5. Advantages

The embodiments described herein may have any one or more of the advantages as described herein. A multiple pulsed signal can be used to activate heating elements within the micro-heater array. The on-pulses are relatively short and have less time to heat. The time periods between the on-pulses can allow for some cooling. Therefore, the micro-heater array may be operated in a manner that is significantly cooler than if a single on-pulse were used. An averaged temperature increase of less than 50° C. or even less than 10° C. may occur when using the multiple pulsed signal.

Gravity may be used to aid in the transfer of a layer or a portion of a layer. A micro-heater array may be positioned so that an entire portion or an entire layer is transferred by such portion or layer releasing from the micro-heater array and adhering or falling onto the substrate. Such a method may be performed to transfer a solid portion or layer, whether or not patterned, from the micro-heater array to the substrate while such portion or layer remains substantially solid.

The ability to transfer already patterned layers can allow for the formation of electronic components without having to use substrate structures, such as cathode separators, well structures, channels or canals, or the like. Processing operations or areas occupied by such substrate structures can be eliminated to reduce costs, improve yield, and increase aperture ratios (for displays and sensor arrays).

### EXAMPLES

The following specific examples are meant to illustrate and not limit the scope of the invention.

### Example 1

This Example demonstrates that a multiple pulsed signal for a heating element can be used to produce less heating compared to a continuous DC signal.

A micro-heater array 40 is designed and fabricated onto a glass substrate (i.e., base material 42) having a nominal thickness of 0.7 mm. The pattern of the micro-heater array 40 is similar to that shown in FIG. 4, wherein, from a plan view, the width and length of each heating element 44 (e.g. a strip) is approximately 85 microns and approximately 62 mm, respectively. The micro-heater array 40 is designed to fit a 4-inch (nominal) diagonal panel with 100 dots per inch in QVGA format (320×RGB×240 subpixels). The material used for heating elements 44 is ITO with a bulk resistivity of approximately 10⁻³ Ω-cm. The ITO is deposited by sputtering and patterned using a conventional photolithography technique. The thickness of the heating elements 44 is approximately 100 nm. The sheet resistance of each heating element 44 is approximately 100 Ω/□. When applying a DC voltage across the heating elements 44, a temperature rise is observed. For input power of approximately 0.1 W per heating element 44 (e.g., strip) for a time of approximately 1 minute, the temperature rise of the glass substrate is approximately 50° C.

When the input power is replaced with a pulsed power supply, having a peak pulse current of approximately 10 mA per heating element 44 (e.g., strip) with pulse width of approximately 100 ms, a temperature rise of more than 50° C. on top of the heater is observed with an IR camera. At a duty cycle of 1000, the average temperature rise of the glass substrate is less than 5° C. No noticeable expansion of the glass substrate is observed.

### Example 2

This Example demonstrates that different materials can be used for the heating element of a multiple pulsed signal micro-heater array.

A micro-heater array 40 is designed and fabricated onto a glass substrate (i.e., base material 42) having a nominal thickness of 0.7 mm. The micro-heater array 40 has heating elements 44 with a pattern that is similar to that shown in FIG. 4, wherein, from a plan view, the width and length of each heating element 44 (e.g. a strip) is approximately 85 microns and approximately 62 mm, respectively. The micro-heater array 40 is designed to fit the 4-inch (nominal) diagonal panel with 100 dots per inch in QVGA format (320×RGB×240 subpixels). The material used for heating elements 44 is Cu with bulk resistivity of approximately 1.7×10⁻⁶ Ω·cm. The Cu is patterned using a conventional lithographic technique. The thickness of each heating element 44 (e.g., strip) is about 400 nm. The resistance of each heating element 44 is approximately 30 Ω. When applying a DC voltage over the heating elements 44, a temperature rise is observed. For input power of approximately 0.1 W per heating element 44 for a time of approximately 1 minute, the temperature rise of the glass substrate is approximately 50° C.

When the input power is replaced with a pulsed power supply, having a peak pulse current of approximately 10 mA per heating element 44 with pulse width of approximately 100 ms, a temperature rise of more than 50° C. on top of the glass substrate is observed with an IR camera. At a duty cycle of 1000, the average temperature rise of the glass substrate is less than 5° C. No noticeable expansion of the glass substrate is observed.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

What is claimed is:

1. A process for forming an electronic device comprising:
placing a substrate adjacent to a heating element and a deposition source, wherein the deposition source lies between the substrate and the heating element;
sending a multiple pulsed signal to the heating element such that the heating element is on and off for a plurality of times; and
depositing a layer over the substrate, wherein:
depositing occurs as a result of sending the multiple pulsed signal to the heating element; and
the layer comprises a material from the deposition source.

2. The process of claim 1, wherein:
a cumulative time period is a time period that starts when a first on/off cycle starts when depositing the layer at a location over the substrate and ends at the end of the last on/off cycle for depositing the layer at the location; and
the heating element is off for at least half of the cumulative time period.

3. The process of claim 2, wherein during the cumulative time period, the heating element is off for at least 90% of the cumulative time period.

4. The process of claim 2, wherein an averaged temperature increase of the deposition source is no more than 50° C. during the cumulative time period.

5. The process of claim 1, wherein the heating element is one of a plurality of heating elements arranged in rows, columns, or both.

6. The process of claim 1, wherein:
the substrate comprises a substrate structure; and
placing comprises placing the substrate structure and the deposition source in contact with each other.

7. The process of claim 1, wherein the deposition source comprises a small molecule organic material.

8. The process of claim 1, wherein the deposition source comprises a polymer.

9. The process of claim 1, wherein the layer comprises an organic active layer.

10. An electronic device formed by the process of claim 9.

11. A process for forming an electronic device comprising:
placing a substrate under a heating element and a deposition source, wherein the deposition source lies between the substrate and the heating element;
sending a signal to the heating element; and
depositing a layer over the substrate, wherein:
depositing occurs as a result of sending the signal to the heating element; and
the layer comprises a material from the deposition source.

12. The process of claim 11, wherein depositing comprises:
contacting the substrate and a portion of the deposition source, wherein the portion lies between the substrate and the heating element; and
moving the substrate and deposition source away from each other after sending the signal to the heating element, wherein after moving, the portion overlies the substrate and is no longer part of the deposition source.

13. The process of claim 12, wherein during contacting, the portion adheres to the substrate.

14. The process of claim 12, further comprising releasing the portion of the deposition source from the deposition source before contacting the substrate.

15. The process of claim 11, wherein the signal comprises a multiple pulsed signal.

16. The process of claim 15, wherein:
a cumulative time period is a time period that starts when a first on/off cycle starts when depositing the layer at a location over the substrate and ends at the end of the last on/off cycle for depositing the layer at the location; and
the heating element is off for at least half of the cumulative time period.

17. The process of claim 16, wherein during the cumulative time period, the heating element is off for at least 90% of the cumulative time period.

18. The process of claim 16, wherein an averaged temperature increase of the deposition source is no more than 50° C. during the cumulative time period.

19. The process of claim 11, wherein the layer comprises an organic active layer.

20. An electronic device formed by the process of claim 19.
